(19) United States
(12) Patent Application Publication
(10) Pub. No.: US 2026/0123075 A1
(43) Pub. Date: Apr. 30, 2026

(54) SEMICONDUCTOR DEVICE WITH OPTICAL STRUCTURE FOR ENHANCING BLUE LIGHT DETECTION

(71) Applicant: SEMICONDUCTOR COMPONENTS INDUSTRIES, LLC, Scottsdale, AZ (US)

(72) Inventors: Byounghee LEE, Boise, ID (US); Swarnal BORTHAKUR, Boise, ID (US); Marc Allen SULFRIDGE, Boise, ID (US)

(73) Assignee: SEMICONDUCTOR COMPONENTS INDUSTRIES, LLC, Scottsdale, AZ (US)

(21) Appl. No.: 18/933,355

(22) Filed: Oct. 31, 2024

(51) Int. Cl. H01L 27/146

(52) U.S. Cl. CPC H10F 39/806; H10F 39/805; H10F 39/8063

(57) ABSTRACT

A semiconductor device is disclosed. The semiconductor device includes a plurality of image pixels. Each image pixel includes a semiconductor region and a single-photon avalanche diode formed in the semiconductor region. Each image pixel also includes an optical structure disposed in the semiconductor region and extending from an upper surface of the semiconductor region into an interior of the semiconductor region. Each image pixel further includes a microlens configured to focus light received by the image pixel into the optical structure.

### TECHNICAL FIELD

The disclosure relates generally to imaging systems, and particularly to imaging sensors that include single-photon avalanche diodes (SPADs) for single-photon detection.

### BACKGROUND

Modern electronic devices such as cellular telephones, cameras, and computers often use digital image sensors. Image sensors, which may also be referred to as imagers, may be formed from a two-dimensional array of image sensing pixels. Each pixel typically includes a photosensitive element, such as a photodiode, which receives incident photons of light and converts the photons into electrical signals. Each pixel often includes a microlens that focuses light onto the photosensitive element.

The inventors of embodiments of the present disclosure have recognized that conventional image sensors with back-side illuminated (BSI) image pixels may suffer from limited functionality in a variety of ways. For example, the inventors of embodiments of the present disclosure have recognized that the timing resolution of BSI image pixels for shorter wavelengths of light may suffer due to the absorption of shorter wavelengths of light occurring primarily near the back-side surface of the BSI image pixel whereas the avalanche happens primarily near the front-side surface of the BSI image pixel. Inventors of embodiments of the present disclosure have also recognized that the electric field at the back-side surface may be weak, which may result in long delay times. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a circuit diagram showing an example single-photon avalanche diode (SPAD) device in accordance with embodiments of the present disclosure.

FIG. 2 illustrates a circuit diagram of an example silicon photomultiplier in accordance with embodiments of the present disclosure.

FIG. 3 illustrates a block diagram of a pixel array and associated readout circuitry for reading out image signals in an example SPAD-based semiconductor device in accordance with embodiments of the present disclosure.

FIG. 4 illustrates a schematic block diagram of an example imaging system with a SPAD-based semiconductor device in accordance with embodiments of the present disclosure.

FIG. 5 illustrates a schematic block diagram of an example positron emission tomography (PET) imaging system with a SPAD-based semiconductor device in accordance with embodiments of the present disclosure.

FIG. 6 illustrates a side cross-sectional view of an image pixel in accordance with embodiments of the present disclosure.

FIG. 7 illustrates a side cross-sectional view of an image pixel in accordance with embodiments of the present disclosure.

FIG. 8A illustrates a side cross-sectional view of an image pixel in accordance with embodiments of the present disclosure.

FIG. 8B illustrates a top view of an image pixel in accordance with embodiments of the present disclosure.

FIG. 9A illustrates a side cross-sectional view of an image pixel in accordance with embodiments of the present disclosure.

FIG. 9B illustrates a top view of an image pixel in accordance with embodiments of the present disclosure.

FIG. 10A illustrates a side cross-sectional view of an image pixel in accordance with embodiments of the present disclosure.

FIG. 10B illustrates a top view of an image pixel in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to. ” Also, the term “couple” or “coupled” is intended to mean either an indirect or direct connection. Thus, if a first device couples to a second device, that connection between the first device and the second device may be through a direct connection or through an indirect connection via other devices and connections.

Terms defining an elevation, such as “above,” “below,” “upper,” and “lower,” shall be locational terms in reference to a direction of light incident upon a pixel array and/or an image pixel. Unless otherwise specified, light entering shall be considered to interact with or pass objects and/or structures that are “above” and “upper” before interacting with or passing objects and/or structures that are “below” or “lower.” Thus, the locational terms may not have any relationship to the direction of the force of gravity.

Imaging systems may include image sensors that sense light by converting impinging photons of light into pairs of electrons and holes that are integrated (collected) in pixel photodiodes within the sensor array. After completion of an integration cycle, collected charge may be converted into a voltage, which is supplied to the output terminals of the sensor. In complementary metal-oxide semiconductor (CMOS) image sensors, the charge to voltage conversion may be accomplished directly in the pixels themselves and the analog pixel voltage may be transferred to the output terminals through various pixel addressing and scanning schemes. The analog pixel voltage can also be later converted on-chip to a digital equivalent and processed in various ways in the digital domain.

In single-photon avalanche diode (SPAD) devices, on the other hand, the photon detection principle is different. The light sensing diode may be biased slightly above its breakdown point, and when an incident photon generates an electron and hole pair, the electron or hole carrier may initiate an avalanche breakdown with additional carriers being generated. The avalanche multiplication may produce a current signal that may be detected by readout circuitry associated with the single-photon avalanche diode. The avalanche process may subsequently be stopped or quenched by lowering the bias below the breakdown point of the diode. Each single-photon avalanche diode may therefore include a passive and/or active quenching circuit for quenching the avalanche.

SPAD devices may be used in multiple ways. For example, in low light level applications, the arriving photons may simply be counted. As another example, SPAD devices may be used to measure photon time-of-flight (ToF) from a synchronized light source to a scene object point and back to the sensor, which may be used to obtain a three-dimensional image of the scene.

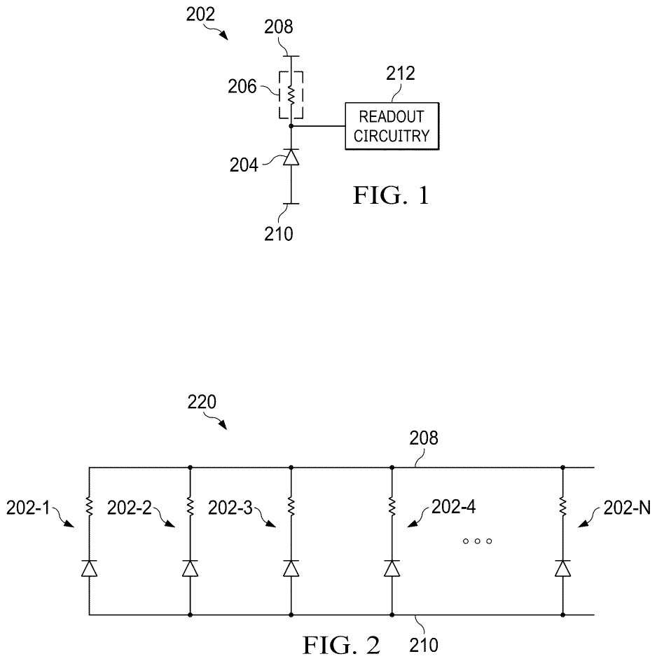

FIG. 1 illustrates a circuit diagram showing an example single-photon avalanche diode (SPAD) device 202 in accordance with embodiments of the present disclosure. As shown in FIG. 1, SPAD device 202 may include single-photon avalanche diode 204 that may be coupled in series with quenching circuitry 206 between a first supply voltage terminal 208 and a second supply voltage terminal 210. In some embodiments, the first supply voltage terminal 208 may be a positive power supply voltage terminal, and the second supply voltage terminal 210 may be a ground power supply voltage terminal. During operation of SPAD device 202, first supply voltage terminal 208 and second supply voltage terminal 210 may be used to bias single-photon avalanche diode 204 to a voltage that is higher than the breakdown voltage of single-photon avalanche diode 204. For the purposes of the present disclosure, the breakdown voltage in Geiger mode may refer to the reverse voltage that can sustain avalanche breakdown in the avalanche diode without needs of additional charge carriers. When single-photon avalanche diode 204 is biased above the breakdown voltage in this manner, absorption of a single-photon may trigger a large, but short-duration, avalanche current through impact ionization.

Quenching circuitry 206 may be used to lower the bias voltage of single-photon avalanche diode 204 below the level of the breakdown voltage. For the purposes of the present disclosure, quenching circuitry 206 may also be referred to as quenching element 206. Lowering the bias voltage of single-photon avalanche diode 204 below the breakdown voltage may stop the avalanche process and corresponding avalanche current. The embodiment of quenching circuitry 206 shown in FIG. 1 illustrates an example where a resistor is used to implement passive quenching circuitry that may, without external control or monitoring, automatically quench the avalanche current once initiated. After the avalanche is initiated, the resulting current rapidly discharges the capacity of the device, lowering the voltage at single-photon avalanche diode 204 to near to the breakdown voltage. The resistance associated with the resistor in quenching circuitry 206 may result in the final current being lower than required to sustain avalanche. Single-photon avalanche diode 204 may then be reset to above the breakdown voltage to enable detection of another photon.

Although the example embodiment of quenching circuitry 206 shown in FIG. 1 utilizes a resistor to implement passive quenching circuitry, other embodiments may utilize active quenching circuitry. Active quenching circuitry may modulate the quench resistance. For example, before a photon is detected, the quench resistance may be set high. Once a photon is subsequently detected and the avalanche is quenched, the quench resistance may be lowered to reduce recovery time. Such active quenching circuitry may reduce the time it takes for SPAD device 202 to be reset. Accordingly, active quenching circuitry may allow SPAD device 202 to detect incident light at a faster rate than when passive quenching circuitry is used, improving the dynamic range of the SPAD device.

SPAD device 202 may also include readout circuitry 212. Readout circuitry 212 may be formed in any of numerous ways to obtain information from SPAD device 202. For example, readout circuitry 212 may include a pulse counting circuit that counts arriving photons. Alternatively, or in addition, readout circuitry 212 may include time-of-flight circuitry that may be used to measure photon time-of-flight (ToF). The photon time-of-flight information may be used to perform depth sensing.

In some embodiments, photons may be counted by an analog counter to form the light intensity signal as a corresponding pixel voltage. Readout circuitry may also include amplification circuitry and/or digital pulse counting circuits. The ToF signal may also be obtained by converting the time of photon flight to a voltage.

Readout circuitry 212 may be coupled to any suitable portion of SPAD device 202 to read single-photon avalanche diode 204. For example, as shown in FIG. 1, readout circuitry 212 may be coupled to a node between single-photon avalanche diode 204 and quenching circuitry 206. In some embodiments, quenching circuitry 206 may be considered as integral with readout circuitry 212.

Because SPAD devices can detect a single incident photon of light, SPAD devices may be effective at imaging scenes with low light levels. Each SPAD device may detect how many photons are received within a given period of time. However, as discussed above, each time a photon is received and an avalanche current initiated, the SPAD device must be quenched and reset before being ready to detect another photon. As incident light levels increase, the dynamic range of the SPAD device may be limited by the reset time. For example, once incident light levels exceed a given level, the SPAD device may be triggered immediately upon being reset. To increase the dynamic range, multiple SPAD devices may be grouped together as described below with reference to the example embodiment illustrated in FIG. 2.

FIG. 2 illustrates a circuit diagram of an example silicon photomultiplier (SiPM) 220 in accordance with embodiments of the present disclosure. As shown in FIG. 2, SiPM 220 may include a group of N number of SPAD devices 202, including for example SPAD devices 202-1, 202-2, 202-3, 202-4, through 202-N. An SiPM such as SiPM 220 may be implemented with any suitable number of SPAD devices 202. For example, an SiPM such as SiPM 220 may be implemented with ten, one hundred, one thousand, or more SPAD devices 202. For the purposes of the present disclosure, SPAD devices such as SPAD devices 202 may also be referred to as SPAD pixels, SPAD-based image pixels, or image pixels.

Although not shown explicitly in FIG. 2, readout circuitry for SiPM 220 may measure the combined output current from all of SPAD-based image pixels 202 in SiPM 220. In this way, the dynamic range of an imaging system including the multiple SPAD-based image pixels 202 of SiPM 220 may be increased. For example, each individual instance of SPAD-based image pixel 202 in SiPM 220 may have an associated probability of an avalanche current being triggered when an incident photon is received. The probability of the avalanche current being triggered depends on both a first probability of an electron being created when a photon reaches the diode as well as a second probability of the electron triggering an avalanche current. The total probability of a photon triggering an avalanche current may be referred to as the photon-detection efficiency (PDE) of the SPAD-based image pixel. By grouping together multiple SPAD-based image pixels 202 in SiPM 220, a more accurate measurement of the incoming incident light may be provided.

In some applications, it may be desirable to use SPAD-based image pixels to obtain image data across an array to allow a higher resolution reproduction of the imaged scene. In such cases, SPAD-based image pixels in a single imaging system may have per-pixel readout capabilities. Alternatively, an array of SiPMs, each including multiple SPAD-based image pixels, may be included in the imaging system. The outputs from each pixel or from each SiPM may be used to generate image data for an imaged scene. The array may be capable of independent detection, whether using a single SPAD-based image pixel or a plurality of SPAD-based image pixels in a line array (for example, an array having a single row and multiple columns or a single column and multiple rows) or an array having more than ten, more than one hundred, or more than one thousand rows and/or columns.

Although there may be numerous different use cases for SPAD-based image pixels as discussed above, the underlying technology used to detect incident light may be the same or similar for the different applications of the SPAD-based image pixels. Regardless of their application, semiconductor-based devices that utilize SPAD-based image pixels may thus be collectively referred to as SPAD-based semiconductor devices. For example, an SiPM with a plurality of SPAD-based image pixels having a common output may be referred to as a SPAD-based semiconductor device. Similarly, an array of SPAD-based image pixels with per-pixel readout capabilities may also be referred to as a SPAD-based semiconductor device. Further, an array of SiPMs with per-SiPM readout capabilities may likewise be referred to as a SPAD-based semiconductor device.

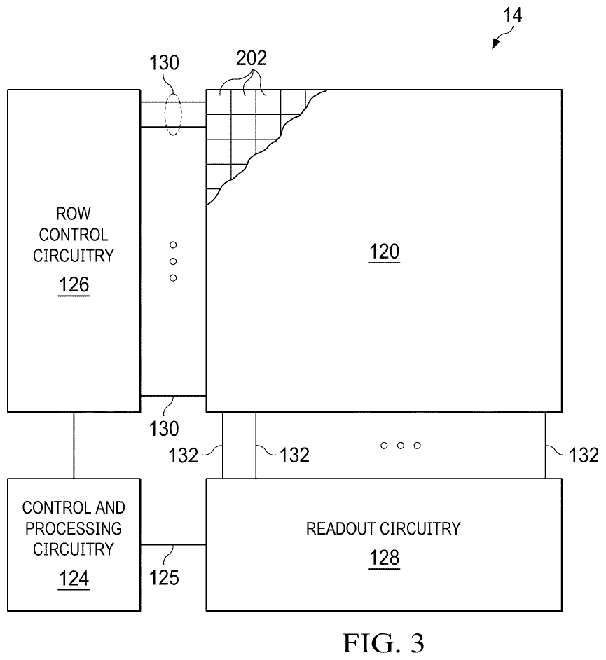

FIG. 3 illustrates a block diagram of a pixel array and associated readout circuitry for reading out image signals in an example SPAD-based semiconductor device 14 in accordance with embodiments of the present disclosure. As shown in FIG. 3, SPAD-based semiconductor device 14 may include an array 120 of SPAD-based image pixels 202 arranged in rows and columns. Array 120 may contain, for example, hundreds or thousands of rows and columns of SPAD-based image pixels 202. Each SPAD-based image pixel 202 may be coupled to an analog pulse counter, for example, which generates a corresponding pixel voltage based on received photons. Each SPAD-based image pixel 202 may additionally or alternatively be coupled to a time-of-flight to voltage converter circuit. In both types of readout circuits, voltages may be stored on pixel capacitors and may later be scanned in a row-by-row fashion.

Control and processing circuitry 124 may be coupled to row control circuitry 126 and readout circuitry 128. Readout circuitry 128 may also be referred to as column control circuitry, column decoder circuitry, processing circuitry, or image readout circuitry. Row control circuitry 126 may receive row addresses from control and processing circuitry 124 and supply corresponding row control signals to SPAD-based image pixels 202 over row control paths 130. One or more conductive lines such as column lines 132 may be coupled to each column of SPAD-based image pixels 202 in array 120. Column lines 132 may be used for reading out image signals from SPAD-based image pixels 202 and for supplying bias signal, such as bias voltages and/or bias currents, to SPAD-based image pixels 202. During pixel readout operations, a pixel row in array 120 may be selected using row control circuitry 126 and image signals generated by SPAD-based image pixels 202 in that pixel row may be read out along column lines 132.

Readout circuitry 128 may receive analog or digital image signals from SPAD-based image pixels 202 over column lines 132. Readout circuitry 128 may include sample-and-hold circuitry for sampling and temporarily storing image signals read out from array 120, amplifier circuitry, analog-to-digital conversion (ADC) circuitry, bias circuitry, column memory, latch circuitry for selectively enabling or disabling the column circuitry, or other circuitry that is coupled to one or more columns of pixels in array 120 for operating SPAD-based image pixels 202 and for reading out signals from SPAD-based image pixels 202. ADC circuitry in readout circuitry 128 may convert analog pixel values received from array 120 into corresponding digital pixel values, which may also be referred to as digital image data or digital pixel data. Alternatively, ADC circuitry may be incorporated into each SPAD-based image pixel 202. Readout circuitry 128 may supply digital pixel data to control and processing circuitry 124 via path 125 for pixels in one or more pixel columns.

The example of SPAD-based semiconductor device 14 having readout circuitry to read out signals from the SPAD-based image pixels in a row-by-row manner is merely illustrative. In other embodiments, the readout circuitry in the image sensor may simply include digital pulse counting circuits coupled to each SPAD-based image pixel. Any other desired readout circuitry arrangement may be used.

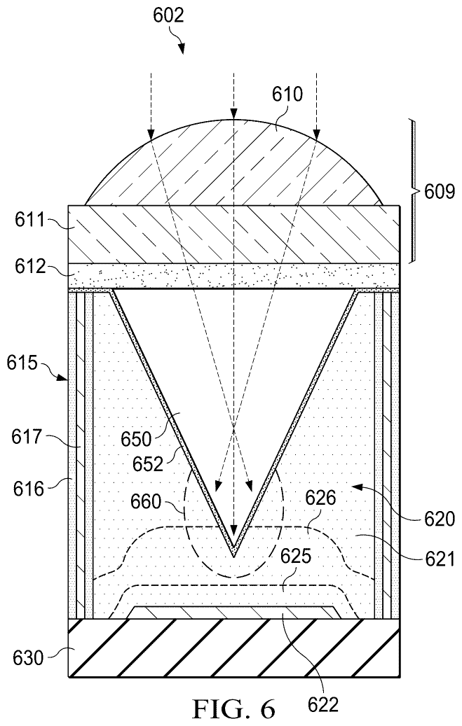

As described in further detail below with reference to FIGS. 6-10B, each SPAD-based image pixel 202 in array 120 may be a back-side illuminated (BSI) SPAD-based image pixel. In some embodiments, array 120 may be part of a multi-die arrangement in which SPAD-based image pixels 202 may be formed in a first substrate and some or all of the corresponding control and readout circuitry may be formed in a second substrate. Further, it should be understood that instead of having an array 120 of SPAD-based image pixels 202 as shown by the example embodiment in FIG. 3, SPAD-based semiconductor device 14 may instead have an array of SiPMs that may each include multiple SPAD-based image pixels 202 with a common output.

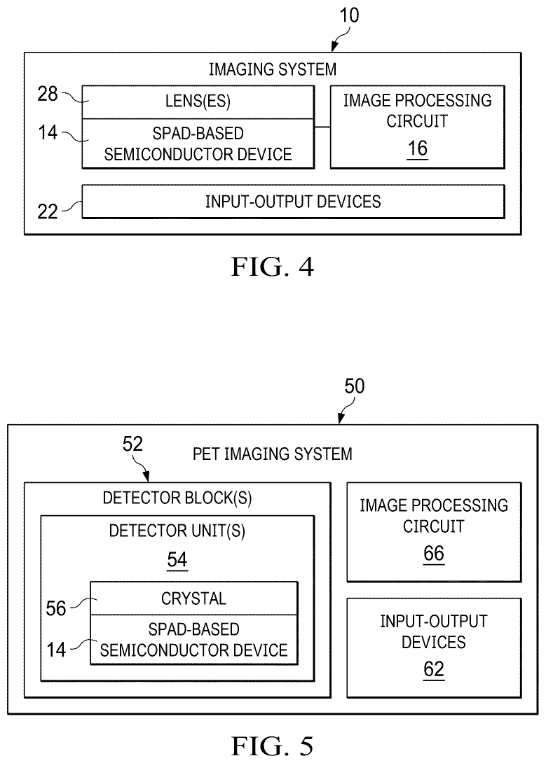

SPAD-based semiconductor devices such as SPAD-based semiconductor device 14 may be utilized in numerous different imaging applications. As described below with reference to FIG. 4 and FIG. 5, SPAD-based semiconductor device 14 may be used in, for example, both LIDAR and PET imaging applications.

FIG. 4 illustrates a schematic block diagram of imaging system 10 with SPAD-based semiconductor device 14 in accordance with embodiments of the present disclosure. In some embodiments, imaging system 10 may be an electronic device such as a digital camera, a computer, a cellular telephone, a medical device, or other electronic device. Imaging system 10 may also be an imaging system of a vehicle. In some embodiments, imaging system 10 may be used for LIDAR applications. Imaging system 10 may include one or more SPAD-based semiconductor devices 14, which may also be referred to as devices, semiconductor devices, image sensors, or SPAD-based image sensors. One or more lenses 28 may optionally cover each SPAD-based semiconductor device 14. During operation, lenses 28 may focus light onto one or more SPAD-based semiconductor device 14. SPAD-based semiconductor device 14 may include SPAD-based image pixels that may convert incident light into digital data. SPAD-based semiconductor device 14 may have any suitable number of SPAD-based image pixels, such as one hundred, one thousand, one million, or more.

SPAD-based semiconductor device 14 may optionally include additional circuitry. For example, SPAD-based semiconductor device 14 may include bias circuitry such as source follower load circuits. As other examples, SPAD-based semiconductor device 14 may also include one or more of sample and hold circuitry, correlated double sampling (CDS) circuitry, amplifier circuitry, analog-to-digital converter (ADC) circuitry, data output circuitry, address circuitry, and/or buffer circuitry and memory.

SPAD-based semiconductor device 14 may be communicatively coupled to image processing circuit 16. Image data from SPAD-based semiconductor device 14 may thus be provided to image processing circuit 16. Image processing circuit 16 may perform image processing functions including, but not limited to, automatic focusing functions, depth sensing, data formatting, adjusting white balance and exposure, implementing video image stabilization, and/or face detection. For example, during automatic focusing operations, image processing circuit 16 may process data gathered by the SPAD-based image pixels to determine the magnitude and direction of movement of lens 28 needed to bring an object of interest into focus. Image processing circuit 16 may process data gathered by the SPAD pixels to determine a depth map of the scene.

Imaging system 10 may provide a user with numerous high-level functions. In a computer or advanced cellular telephone, for example, a user may be provided with the ability to run user applications. To implement these functions, imaging system 10 may include input-output devices 22 such as keypads, buttons, input-output ports, joysticks, and/or displays. Additional storage and processing circuitry such as volatile and nonvolatile memory, microprocessors, microcontrollers, digital signal processors, application specific integrated circuits, and/or other processing circuits may also be included in imaging system 10.

Input-output devices 22 may include output devices that work in combination with SPAD-based semiconductor device 14. For example, a light-emitting component may be included in the imaging system to emit light, such as infrared light or light of any other desired type. SPAD-based semiconductor device 14 may measure the reflection of the light off of an object to measure distance to the object in a light detection and ranging (LIDAR) scheme.

FIG. 5 illustrates a schematic block diagram of an example positron emission tomography (PET) imaging system 50 that includes a SPAD-based semiconductor device 14 in accordance with embodiments of the present disclosure. In some embodiments, PET imaging system 50 may be a medical device such as a PET scanner or other electronic device. PET imaging system 50 may also be referred to as a SPAD-based imaging system or a SPAD-based PET imaging system.

PET imaging system 50 may include one or more detector blocks 52. Each detector block 52 may include one or more detector units 54. Each detector unit 54 may include a respective SPAD-based semiconductor device 14 and crystal 56. Crystal 56 may also be referred to as a scintillator. Crystal 56 may absorb ionizing radiation such as gamma rays caused, for example, by a radioactive tracer used in the PET imaging system. In response to the gamma rays, crystal 56 may emit light in the visible spectrum. For example, crystal 56 may emit blue light in response to the absorption of gamma rays. Crystal 56 may be formed with lutetium-yttrium oxyorthosilicate (LYSO), or any material suitable to serve as a scintillator.

One or more lenses may optionally cover each SPAD-based semiconductor device 14. During operation, lenses may focus light from crystal 56 onto SPAD-based semiconductor device 14. SPAD-based semiconductor device 14 may include SPAD-based image pixels, such as SPAD-based image pixels 202 described above with reference to FIGS. 1-3, that may convert light from crystal 56 into digital data. And as described in further detail below with reference to FIGS. 6-10B, each SPAD-based image pixel may be covered by a respective microlens and/or nanophotonic lens. In some embodiments, one or more blue-pass filters may also be used to pass wavelengths of blue light and to block infrared and other wavelengths of visible light. For example, a universal blue-pass filter may be included within detector block 52 of PET imaging system 50 to pass wavelengths of blue light and to block infrared and other wavelengths of visible light from reaching SPAD-based semiconductor device 14. Further, as described in further detail below with reference to FIGS. 6-10B, various embodiments of image pixels within a SPAD-based semiconductor device such as SPAD-based semiconductor device 14 may optionally include a pixel-level blue-pass filter.

Image data from SPAD-based semiconductor device 14 may be provided to image processing circuit 66. Image processing circuit 66 may be used to perform image processing functions for PET imaging system 50. In some cases, some or all of the control circuitry within PET imaging system 50 may be formed integrally with image processing circuit 66. Further, PET imaging system 50 may provide a user with numerous high-level functions. To implement these functions, PET imaging system 50 may include one or more input-output devices 62 such as keypads, buttons, input-output ports, joysticks, and displays such as touch-sensitive displays. Additional storage and processing circuitry such as volatile and nonvolatile memory, microprocessors, microcontrollers, digital signal processors, application specific integrated circuits, and/or other processing circuits may also be included in PET imaging system 50.

Various examples of SPAD-based image pixels are disclosed herein. To improve the fill factor of an array of SPAD-based image pixels, SPAD-based image pixels may be implemented as back-side illuminated image pixels, where the lens may be formed on the back surface of the semiconductor substrate on the opposite side of the single-photon avalanche diode from the dielectric stack that includes one or more dielectric layers and corresponding metal routing layers. With such a back-side illumination configuration, light received at the back side of the image pixel travels through the semiconductor substrate to the single-photon avalanche diode, which may be implemented by doping on the front side of the image pixel. The electric field associated with the p-n junction of the single-photon avalanche diode may be strongest in the avalanche region of the single-photon avalanche diode, and may weaken exponentially with increasing distance away from avalanche region toward the back-side surface of the image pixel. Thus, the speed at which carriers formed by the absorption of a photon of light in semiconductor substrate may be affected by the depth within the semiconductor substrate at which photon absorption occurs.

Various imaging applications, such as the PET imaging system described above with reference to FIG. 5, may be directed to detecting blue light. For the purposes of the present disclosure, blue light may refer to light with a wavelength range between 380 and 500 nanometers. In a SPAD-based image pixel, photons of blue light may be absorbed within a shallow absorption area of the semiconductor substrate due to the shorter wavelength of blue light relative to the wavelengths of other visible light. Thus, various embodiments of image pixels described herein may utilize optical structures with a material having a lower absorption rate than the semiconductor region, formed for example with silicon, in which the single-photon avalanche diode is implemented. The optical structures may transmit light, including for example blue light, received by the back-side illuminated image pixel deeper into the semiconductor region in which the single-photon avalanche diode is formed. By transmitting photons of light deeper into the semiconductor region where they may be absorbed closer to the avalanche region of the single-photon avalanche diode, the optical structures may improve the charge transfer time associated with absorbed photons of light. The single photon timing resolution (SPTR) of the individual image pixel may therefore be improved. Likewise, the SPTR of the silicon photomultiplier (SiPM) and/or SPAD-based semiconductor device in which image pixel is implemented may also be improved. The improved SPTR may be particularly pronounced for blue light applications due to the shorter wavelength of blue light relative to the wavelengths of other visible light and the tendency of blue light to be absorbed within a shallow area of the semiconductor substrate in which the single-photon avalanche diode is formed.

FIG. 6 illustrates a side cross-sectional view of image pixel 602 in accordance with embodiments of the present disclosure. Image pixel 602 may be a SPAD-based image pixel and may also be referred to as SPAD-base image pixel 602 or SPAD pixel 602. Although a single instance of image pixel 602 is illustrated in FIG. 6, image pixel 602 may be one of multiple image pixels in an array. For example, image pixel 602 may represent an embodiment of each of the plurality of SPAD-based image pixels 202 in array 120 of SPAD-based semiconductor device 14 described above with reference to FIG. 3.

Image pixel 602 may include lens layer 609, trench regions 615, semiconductor region 620, dielectric stack 630, and optical structure 650. Image pixel 602 may also include a single-photon avalanche diode formed in semiconductor region 620. Semiconductor region 620 may be formed from a silicon substrate or from epitaxial growth on a silicon substrate. Doping may be added to semiconductor substrate to provide the single-photon avalanche diode. For example, semiconductor region 620 may include an n-type doping region 622 within a p-type epitaxial region 621. The single-photon avalanche diode may be formed by the p-n junction of the p-type epitaxial region 621 and n-type doping region 622.

In some embodiments, image pixel 602 may be a back-side illuminated image pixel. For example, lens layer 609 may be formed on the back surface of semiconductor region 620 on the opposite side of the single-photon avalanche diode from dielectric stack 630, which may include one or more dielectric layers and corresponding metal routing layers.

Lens layer 609 may include microlens 610. Microlens 610 may be formed with either an organic or an inorganic material. For example, microlens 610 may in some embodiments be formed with an inorganic oxide material. In other embodiments, microlens 610 may be formed with an organic material, such as an acrylic-based polymer. The upper surface of 610 may have a spherical convex shape. The lower surface of microlens 610 may have a planar shape. Microlens 610 may thus refract the light received by image pixel 602 and focus that light into underlying elements of image pixel 602. Specifically, microlens 610 may focus light received by image pixel 602 into the optical structure 650 disposed within semiconductor region 620. In some embodiments, lens layer 609 may also include a planar layer 611. Planar layer 611 may be formed with the same material, such as an acrylic-based polymer, as microlens 610. As shown in FIG. 6, the lower surface of microlens 610 may sit atop the upper surface of planar layer 611. The inclusion of planar layer 611 may prevent physical stresses incurred during the process of forming microlens 610 from translating to underlying features of image pixel 602. However, in some embodiments, planar layer 611 may be omitted from lens layer 609, and microlens 610 may sit directly on top of features underlying lens layer 609.

In some embodiments, image pixel 602 may also include blue-pass filter 612. Blue-pass filter 612 may be configured to pass blue light received and focused by microlens 610 to the underlying features of image pixel 602. Blue-pass filter 612 may be, for example, either a dye-based or a pigment based absorptive filter, or an interference filter, configured to pass wavelengths of blue light and to block infrared and other wavelengths of visible light. Blue-pass filter 612 may be used, for example, in embodiments where image pixel 602 is part of a SPAD-based semiconductor device utilized to detect blue light from a scintillator such as crystal 56 in PET imaging system 50 described above with reference to FIG. 5. As shown in FIG. 6, blue-pass filter 612 may be located between microlens 610 and the semiconductor region 620 in which the single-photon avalanche diode is formed. However, in embodiments where blue-pass filter 612 is omitted from image pixel 602 and added separate from and above image pixel 602, microlens 610 or planar layer 611 of lens layer 609 may be located directly above semiconductor region 620 and/or one or more optical structures included within semiconductor region 620.

Dielectric stack 630 may be located under semiconductor region 620. Dielectric stack 630 may include a dielectric material, such as silicon dioxide. Dielectric stack 630 may also include one or more layers of patterned metal that may be used for signal routing and for electrically coupling to the single-photon avalanche diode within semiconductor region 620.

In some embodiments, image pixel 602 may further include trench region 615 surrounding the sides of semiconductor region 620. During manufacture of image pixel 602, trench region 615 may be formed, for example, by an etch process from the front side of image pixel 602 prior to the formation of dielectric stack 630 on the front side. Trench region 615 may include a dielectric material 616, such as silicon dioxide, to electrically isolate one instance of image pixel 602 from neighboring instances of image pixel 602 in an array. As shown in FIG. 6, trench region 615 may also include fill material 617. Fill material 617 may prevent photons of light from passing through one instance of image pixel 602 to a neighboring instance of image pixel 602, thereby reducing or eliminating unwanted optical crosstalk between neighboring instances of image pixel 602. Fill material 617 may be formed of an absorptive material. For example, fill material 617 may include a metal such as tungsten. The absorptive material may prevent secondary photons generated during the avalanche from passing into a neighboring image pixel and causing optical crosstalk. In some embodiments, a metal such as tungsten may be used as fill material 617 throughout for the entire span of trench region 615. In other embodiments, and to improve manufacturability, trench region 615 may have a combination of fill materials, including for example polysilicon and metal. In such embodiments, metal may be used as fill material 617 near the front-side of image pixel to block secondary photons generated in the avalanche region. Polysilicon may then be used as the fill material 617 for rest of trench region 615. In either such embodiments described above, fill material 617 may be conductive to allow electrical biasing of trench region 615, thereby reducing dark current generation.

As described above, the single-photon avalanche diode of image pixel 602 may be formed by the p-n junction of the p-type epitaxial region 621 and the n-type doping region 622 in semiconductor region 620. As also described above, the single-photon avalanche diode may be electrically biased above its breakdown point. Thus, when an incident photon of light generates an electron or a hole, the electron or hole carrier initiates an avalanche breakdown with additional carriers being generated. The avalanche multiplication may produce a current signal that may be detected by readout circuitry associated with image pixel 602.

As shown in FIG. 6, avalanche region 625 may form around n-type doping region 622. Further, depletion region 626 may form in an area around avalanche region 625. The electric field associated with the biased p-n junction may be strongest in avalanche region 625 and may weaken exponentially with increasing distance away from avalanche region 625 and depletion region 626 and toward the upper surface of semiconductor region 620. Thus, the speed at which carriers formed by the absorption of a photon of light in semiconductor region 620 may be affected by the depth within semiconductor region 620 at which the absorption occurs.

As described in further detail directly below, image pixel 602 may include optical structure 650. Optical structure 650 may transmit photons of light deeper into semiconductor region 620 where they may be absorbed closer to the avalanche region of the single-photon avalanche diode of image pixel 602. Optical structure 650 may thus improve the charge transfer time associated with absorbed photons of light, and therefore improve the single photon timing resolution (SPTR) of image pixel 602 and/or the SPTR of a silicon photomultiplier (SiPM) or SPAD-based semiconductor device in which image pixel 602 may be implemented. The improved SPTR may be particularly pronounced for applications in which blue light is detected by image pixel 602. Due to the shorter wavelength of blue light relative to other wavelengths of visible light, blue light may be more susceptible than other wavelengths of visible light to being absorbed within a shallow depth of semiconductor region 620 for embodiments without optical structure 650.

Optical structure 650 may be disposed in semiconductor region 620 extending from an upper surface of semiconductor region 620 into an interior of semiconductor region 620. Optical structure 650 may be formed with a material having a lower absorption rate than the material, such as silicon, forming semiconductor region 620. The material of optical structure 650 may thus be suitable to transmit photons of light into the interior of semiconductor region 620. Optical structure 650 may comprise, for example, silicon dioxide, the same acrylic-based polymer forming microlens 610, or any other material that has a lower absorption rate than semiconductor region 620 and that may be suitable to transmit photons of light into semiconductor region 620. In some embodiments, optical structure 650 may have an inverse pyramid shape extending downward from the upper surface of semiconductor region 620 into the interior of semiconductor region 620. In other embodiments, optical structure 650 may have a conical shape, a cuboid shape, or any other shape extending downward from the upper surface of semiconductor region 620 suitable to transmit photons of light received by image pixel 602 into the interior of semiconductor region 620.

Optical structure 650 may transmit photons of light received by image pixel 602 deep into the interior of semiconductor region 620 where the electric field of the biased single-photon avalanche diode is stronger than at the upper surface of semiconductor region 620. For example, optical structure 650 may extend into depletion region 626 of the single-photon avalanche diode. Accordingly, the absorption area 660 for photons of blue light may at least partially overlap with depletion region 626 of the single-photon avalanche diode. Absorption area 660 may represent the area within semiconductor region 620 in which a majority of incident photons of blue light are absorbed. By utilizing optical structure 650 to locate absorption area 660 in areas of semiconductor region 620 where the electric field associated with the p-n junction the single-photon avalanche diode is stronger, the single photon timing resolution (SPTR) of image pixel 602 may be improved.

As also shown in FIG. 6, image pixel 602 may include passivation layer 652 at the border between optical structure 650 and semiconductor region 620. During manufacture, the area to be occupied by optical structure 650 may first be formed with a back-side etch in semiconductor region 620. Subsequently, passivation layer 652 may be formed on the etched surface of semiconductor region 620, and the remaining open area may be filled with any suitable material as described above to form optical structure 650. Passivation layer 652 may help passivate dangling bond defects at the etched surface of semiconductor region 620 caused by the etching process and reduce dark current generation. Further manufacturing steps may be utilized to reduce the number of defects created at the etched surface of semiconductor region 620 prior to passivation. For example, during the etching process, the etching may be performed along planes corresponding to the crystallographic structure of the silicon that forms semiconductor region 620. Thus, in some embodiments, passivation layer 652 and optical structure 650 may be formed along the crystallographic structure of semiconductor region 620.

Passivation layer 652 may be formed with a high-k dielectric. For example, passivation layer 652 may include layers of one or more of hafnium oxide, aluminum oxide, and/or tantalum oxide. From an optical standpoint, passivation layer 652 may also improve the passage of light into semiconductor region 620. Specifically, passivation layer 652 may provide an intermediate refractive index between optical structure 650 and semiconductor region 620, thereby improving the passage of light into semiconductor region 620 and reducing the reflection of light at the border of semiconductor region 620.

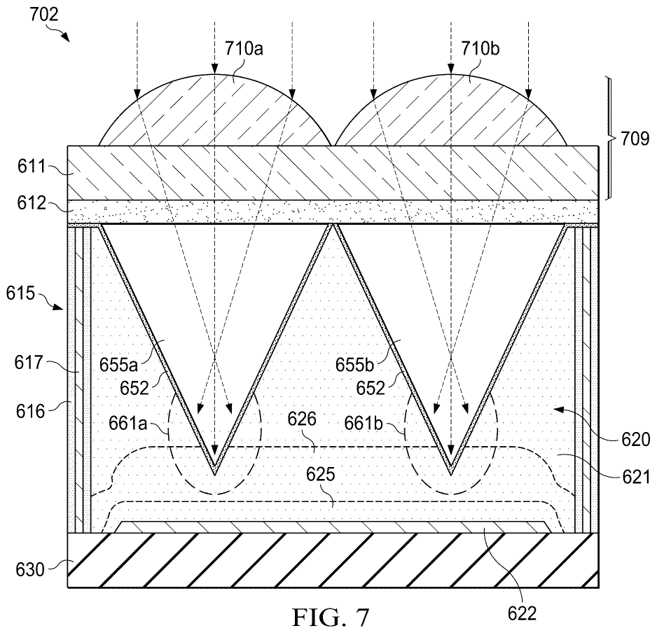

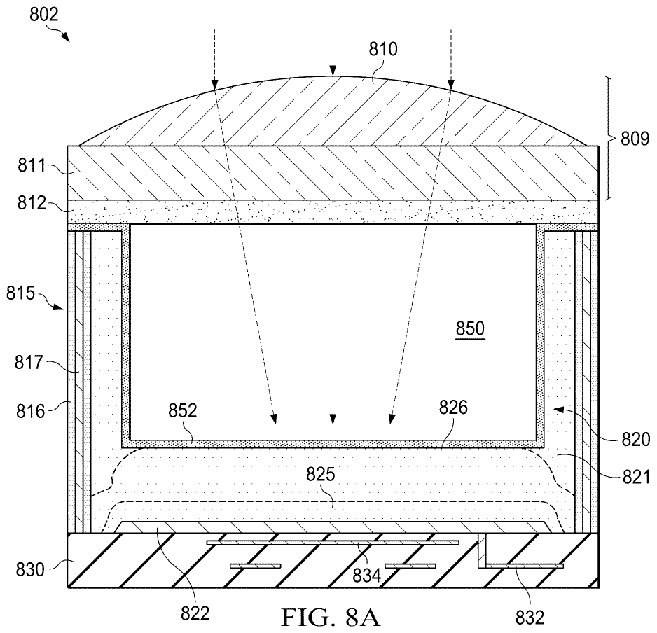

FIG. 7 illustrates a side cross-sectional view of image pixel 702 in accordance with embodiments of the present disclosure. Image pixel 702 may be a SPAD-based image pixel and may also be referred to as SPAD-based image pixel 702 or SPAD pixel 702. Although a single instance of image pixel 702 is illustrated in FIG. 7, image pixel 702 may be one of multiple image pixels in an array. For example, image pixel 702 may represent an embodiment of each of the plurality of SPAD-based image pixels 202 in array 120 of SPAD-based semiconductor device 14 described above with reference to FIG. 3.

As shown in FIG. 7, certain features of image pixel 702 may be configured in a similar manner as image pixel 602 described above with reference to FIG. 6. For example, similar to image pixel 602, image pixel 702 may include trench regions 615, dielectric stack 630, blue-pass filter 612. Further similar to image pixel 602, image pixel 702 may include a semiconductor region 620 having a p-type epitaxial region 621 and an n-type doping region 622 that collectively form a single-photon avalanche diode. But as shown in FIG. 7, lens layer 709 may be configured with multiple microlenses corresponding to multiple optical structures extending into semiconductor region 620. Specifically, image pixel 702 may include a plurality of optical structures 655a and 655b disposed in semiconductor region 620 and extending from an upper surface of the semiconductor region to the interior of semiconductor region 620. Image pixel 702 may also include a plurality of microlenses 710a and 710b respectively configured to focus light received by image pixel 702 into the plurality of optical structures 655a and 655b.

Similar to optical structure 650 described above with reference to FIG. 6, optical structures 655a and 655b shown in FIG. 7 may be formed with a material that has a lower absorption rate than the material, such as silicon, of semiconductor region 620. Optical structures 655a and 655b may thus be suitable to transmit photons of light into the interior of semiconductor region 620. Optical structures 655a and 655b may comprise, for example, silicon dioxide, the same acrylic-based polymer forming microlens 610, or any other material that may have a lower absorption rate than the material of semiconductor region 620, and that may be suitable to transmit photons of light into semiconductor region 620. In some embodiments, optical structure 650 may have an inverse pyramid shape extending downward from the upper surface of semiconductor region 620 into the interior of semiconductor region 620. In other embodiments, optical structures 655a and 655b may have a conical shape, a cuboid shape, or any other shape extending downward from the upper surface of semiconductor region 620 and suitable to transmit photons of light received by image pixel 602 into the interior of semiconductor region 620.

The plurality of optical structures 655a and 655b may transmit photons of light received by image pixel 702 deep into the interior of semiconductor region 620 where the electric field of the biased single-photon avalanche diode is stronger than at the upper surface of semiconductor region 620. For example, the plurality of optical structures 655a and 655b may extend into depletion region 626 of the single-photon avalanche diode. Accordingly, the absorption areas 661a and 661b for photons of blue light may at least partially overlap with depletion region 626 of the single-photon avalanche diode. By utilizing optical structures 655a and 655b to locate absorption areas 661a and 661b in areas of semiconductor region 620 where the electric field associated with the p-n junction the single-photon avalanche diode is stronger, the single photon timing resolution (SPTR) of image pixel 702 may be improved.

As shown in FIG. 7, image pixel 702 may include passivation layer 652 at the border between each of optical structure 655a and 655b and semiconductor region 620. In a similar manner as described above with reference to FIG. 6, passivation layer 652 may be added during manufacturing to help passivate defects at the etched surface of semiconductor region 620. Passivation layer 652 may also provide an intermediate refractive index between semiconductor region 620 and the plurality of optical structures 655a and 655b, thereby improving the passage of light from optical structures 655a and 655b into semiconductor region 620 and reducing the reflection of light at the border of semiconductor region 620 and the plurality of optical structures 655a and 655b.

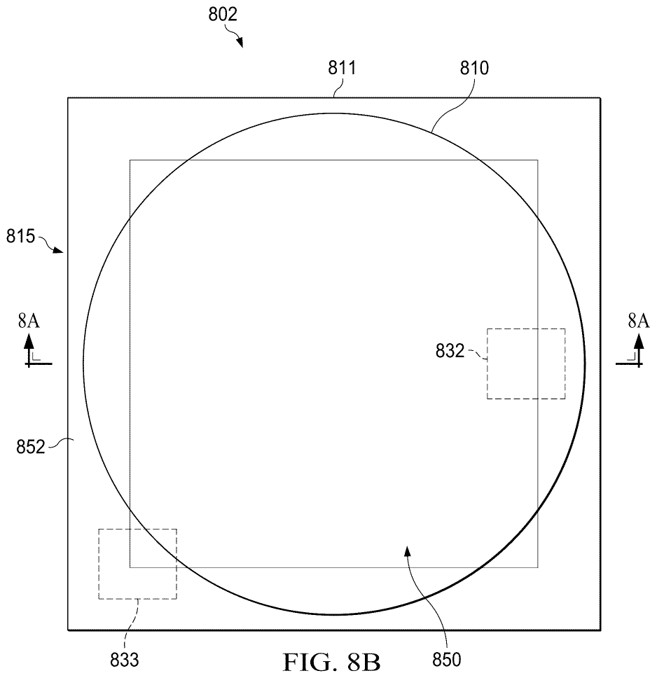

FIG. 8A illustrates a side cross-sectional view of image pixel 802 in accordance with embodiments of the present disclosure. FIG. 8B illustrates a top view of image pixel 802 in accordance with embodiments of the present disclosure. The cross-sectional view of FIG. 8A is taken from the perspective of cutline 8A in FIG. 8B.

Image pixel 802 may be a SPAD-based image pixel and may also be referred to as SPAD-based image pixel 802 or SPAD pixel 802. Although a single instance of image pixel 802 is illustrated in FIGS. 8A and 8B, image pixel 802 may be one of multiple image pixels in an array. For example, image pixel 802 may represent an embodiment of each of the plurality of SPAD-based image pixels 202 in array 120 of SPAD-based semiconductor device 14 described above with reference to FIG. 3.

Image pixel 802 may include lens layer 809, trench regions 815, semiconductor region 820, dielectric stack 830, and light pipe 850. Image pixel 802 may also include a single-photon avalanche diode formed in semiconductor region 820. Semiconductor region 820 may be formed from a silicon substrate or from epitaxial growth on a silicon substrate. Doping may be added to semiconductor substrate to provide the single-photon avalanche diode. For example, semiconductor region 820 may include an n-type doping region 822 within a p-type epitaxial region 821. The single-photon avalanche diode may be formed by the p-n junction of the p-type epitaxial region 821 and n-type doping region 822.

In some embodiments, image pixel 802 may be a back-side illuminated (BSI) image pixel. For example, lens layer 809 may be formed on the back surface of semiconductor region 820 on the opposite side of the single-photon avalanche diode from dielectric stack 830, which may include one or more dielectric layers and corresponding metal routing layers.

Lens layer 809 may include a single microlens 810. Microlens 810 may be formed with either an organic or an inorganic material. For example, microlens 810 may in some embodiments be formed with an inorganic oxide material. In other embodiments, microlens 810 may be formed with an organic material, such as an acrylic-based polymer. The upper surface of microlens 810 may have a spherical convex shape. The lower surface of microlens 810 may have a planar shape. Microlens 810 may thus refract the light received by the image pixel and focus that light into underlying elements of image pixel 802. Specifically, microlens 810 may focus light received by image pixel 802 into the light pipe 850 disposed in semiconductor region 820 above the single-photon avalanche diode. In some embodiments, lens layer 809 may also include a planar layer 811. Planar layer 811 may be formed with the same material, such as acrylic-based polymer, as microlens 810. As shown in FIG. 8A, the lower surface of microlens 810 may sit atop the upper surface of planar layer 811. The inclusion of planar layer 811 may prevent physical stresses incurred during the process of forming microlens 810 from translating to underlying features of image pixel 802. However, in some embodiments, planar layer 811 may be omitted from lens layer 809, and microlens 810 may sit directly on top of features underlying lens layer 809.

In some embodiments, image pixel 802 may also include blue-pass filter 812. Blue-pass filter 812 may be configured to pass blue light received and focused by microlens 810 to the underlying features of image pixel 802. Blue-pass filter 812 may be, for example, either a dye-based or a pigment based absorptive filter, or an interference filter, configured to pass wavelengths of blue light and to block infrared and other wavelengths of visible light. Blue-pass filter 812 may be used, for example, in embodiments where image pixel 802 is part of a SPAD-based semiconductor device utilized to detect blue light from a scintillator such as crystal 56 in PET imaging system 50 described above with reference to FIG. 5. As shown in FIG. 8, blue-pass filter 812 may be located between microlens 810 and the semiconductor region 820 in which the single-photon avalanche diode is formed. However, in embodiments where blue-pass filter 812 is omitted, microlens 810 or planar layer 811 of lens layer 809 may be located directly above semiconductor region 820 and one or more light pipes included within semiconductor region 820.

Dielectric stack 830 may be located under semiconductor region 820. Dielectric stack 830 may include a dielectric material, such as silicon dioxide. Dielectric stack 830 may also include one or more layers of patterned metal that may be used for signal routing and for coupling to the single-photon avalanche diode within semiconductor region 820. For example, dielectric stack 830 may include metal layers to form a first diode electrode 832 and a second diode electrode 833 collectively illustrated in FIGS. 8A and 8B. As shown in FIG. 8A, dielectric stack 830 may also include reflector 834. Although the majority of light, including blue light for example, may be absorbed within semiconductor region 820, some photons of light may initially pass through semiconductor region 820 and into dielectric stack 830 without being absorbed. Reflector 834 may be configured to reflect unabsorbed photons of light back into semiconductor region 820 toward the avalanche region of the single-photon avalanche diode. Those initially-unabsorbed photons may thus be absorbed during a second pass through semiconductor region 820. In embodiments of image pixel 802 directed to blue-light applications, reflector 834 may be configured specifically to reflect blue light. For example, reflector 834 may be formed with a metal such as aluminum, titanium, titanium nitride, or any other metal or metal alloy suitable for reflecting blue light back into semiconductor region 820.

In some embodiments, image pixel 802 may further include trench region 815 surrounding the sides of semiconductor region 820. During manufacture of image pixel 802, trench region 815 may be formed, for example, by an etch process from the front side of image pixel 802 prior to the formation of dielectric stack 830 on the front side. Trench region 815 may include a dielectric material 816, such as silicon dioxide, to electrically isolate one instance of image pixel 802 from neighboring instances of image pixel 802 in an array. As shown in FIG. 8, trench region 815 may also include fill material 817. Fill material 817 may be formed of an absorptive material. For example, fill material 817 may include a metal such as tungsten. Fill material 817 may thus prevent photons of light from passing through an instance of image pixel 802 to a neighboring instance of image pixel 802, thereby reducing or eliminating unwanted optical crosstalk between neighboring instances of image pixel 802.

As described above, the single-photon avalanche diode of image pixel 802 may be formed by the p-n junction of the p-type epitaxial region 821 and the n-type doping region 822 in semiconductor region 820. As also described above, the single-photon avalanche diode may be electrically biased above its breakdown point. Thus, when an incident photon of light generates an electron or hole, the electron or hole carrier initiates an avalanche breakdown with additional carriers being generated. The avalanche multiplication may produce a current signal that may be detected by readout circuitry associated with image pixel 802.

As shown in FIG. 8A, avalanche region 825 may form around n-type doping region 822. Further, depletion region 826 may form in an area around avalanche region 825. The electric field associated with the biased p-n junction may be stronger in areas of semiconductor region 820 closer to the p-n junction, and weaker in areas of semiconductor region 820 further away from the p-n junction and toward the upper surface of semiconductor region 820. Thus, the speed at which carriers formed by the absorption of a photon of light in semiconductor region 820 may be affected by the depth within semiconductor region 820 at which the absorption occurs. As described in further detail directly below, image pixel 802 may include light pipe 850 to transmit photons of light deeper within semiconductor region 820 where they may be absorbed closer to the avalanche region of the single-photon avalanche diode of image pixel 802. Light pipe 850 may thus improve the charge transfer time associated with absorbed photons of light, and therefore improve the single photon timing resolution (SPTR) of image pixel 802. The SPTR of a silicon photomultiplier (SiPM) and/or SPAD-based semiconductor device in which image pixel 802 is implemented may likewise be improved. The improved SPTR may be particularly pronounced for applications in which blue light is detected by image pixel 802. Due to the shorter wavelength of blue light relative to other wavelengths of visible light, blue light may be more susceptible to being absorbed within a shallow depth of semiconductor region 820 in embodiments without light pipe 850.

As shown in FIG. 8A, light pipe 850 may extend from an upper surface of semiconductor region 820 to an interior area of semiconductor region 820 above the single-photon avalanche diode. Light pipe 850 may represent an embodiment of the optical structure 650 described above and may thus also be referred to as an optical structure. As shown in the top view of FIG. 8B, light pipe 850 may be symmetrically configured about the center of image pixel 802. Moreover, as shown in FIG. 8A, light pipe 850 may be disposed in semiconductor region 820 above the single-photon avalanche diode. For example, light pipe 850 may extend from the upper surface of semiconductor region 820 downward into semiconductor region 820 at a depth such that light pipe 850 overlaps with depletion region 826 of the single-photon avalanche diode.

Light pipe 850 may be formed with a material that has a lower absorption rate than the material, for example silicon, of semiconductor region 820. Light pipe 850 may thus be suitable to transmit photons of light into the interior of semiconductor region 820. In some embodiments, light pipe 850 may comprise the same material as lens layer 809. Light pipe 850 may comprise, for example, silicon dioxide, the same acrylic-based polymer forming microlens 810, or any other material that has a lower absorption rate than the material of semiconductor region 820 and may thus be suitable to transmit photons of light into semiconductor region 820. In some embodiments, light pipe 850 may have cuboid shape extending downward from the upper surface of semiconductor region 820 into the interior of semiconductor region 820. As shown in the top view of FIG. 8B, the top-view cross section of light pipe 850 may have a square shape corresponding to the top-view square shape of image pixel 802 as a whole. In other embodiments, light pipe 850 may have a cylindrical shape, or any other shape extending downward from the upper surface of semiconductor region 820 suitable to transmit photons of light received by image pixel 802 into the interior of semiconductor region 820.

Light pipe 850 may transmit photons of light received by image pixel 802 deep into the interior of semiconductor region 820 where the electric field of the biased single-photon avalanche diode is stronger than at the upper surface of semiconductor region 820. For example, light pipe 850 may extend into depletion region 826 of the single-photon avalanche diode. Accordingly, the absorption area for photons of blue light may at least partially overlap with depletion region 826 of the single-photon avalanche diode. By utilizing light pipe 850 to locate the absorption area in areas of semiconductor region 820 where the electric field associated with the p-n junction the single-photon avalanche diode is stronger, the single photon timing resolution (SPTR) of image pixel 802 may be improved.

As also shown in FIG. 8A, image pixel 802 may include passivation layer 852 at the border between light pipe 850 and semiconductor region 820. During manufacture, the area to be occupied by light pipe 850 may first be formed with a back-side etch in semiconductor region 820. Passivation layer 852 may then be formed on the etched surface of semiconductor region 820. Passivation layer 852 may help passivate defects at the etched surface of semiconductor region 820. Subsequently, the remaining open area may be filled with any suitable material as described above to form light pipe 850.

Passivation layer 852 may be formed with a high-k dielectric. For example, passivation layer 852 may include layers of one or more of hafnium oxide, aluminum oxide, and/or tantalum oxide. From an optical standpoint, passivation layer 852 may also improve the passage of light into semiconductor region 820. Specifically, passivation layer 852 may provide an intermediate refractive index between light pipe 850 and semiconductor region 820, thereby improving the passage of light into semiconductor region 820 and reducing the reflection of light at the border of semiconductor region 820.

Although FIGS. 8A and 8B illustrate an embodiment in which image pixel 802 includes a single instance of light pipe 850, other embodiments of image pixels as disclosed herein may include a plurality of light pipes disposed in semiconductor region 820 above the single-photon avalanche diode. Specifically, other embodiments may include two or more instances of a light pipe extending from the upper surface of semiconductor region 820 into the interior of semiconductor region 820 above the single-photon avalanche diode. In such embodiments, the different instances of the light pipe may transmit light received by image pixel 802 deep into the interior of semiconductor region 820 where the electric field of the biased single-photon avalanche diode is stronger than at the upper surface of semiconductor region 820. For example, the different instances of the light pipe may extend into depletion region 826 of the single-photon avalanche diode. Accordingly, the absorption area for photons of blue light transmitted through the different instances of the light pipe may at least partially overlap with depletion region 826 of the single-photon avalanche diode.

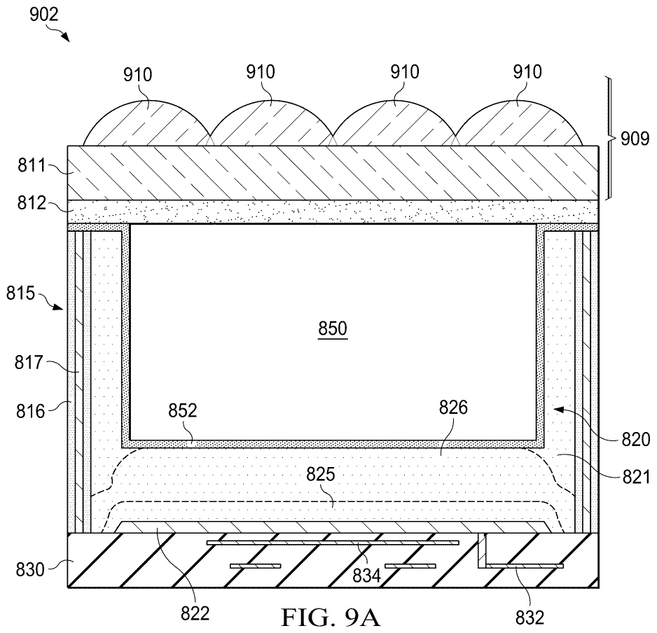

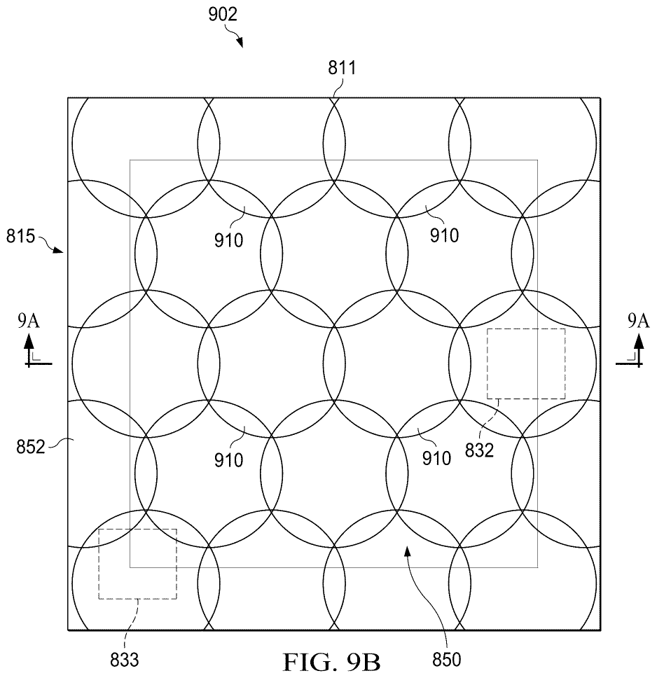

FIG. 9A illustrates a side cross-sectional view of image pixel 902 in accordance with embodiments of the present disclosure. FIG. 9B illustrates a top view of image pixel 902 in accordance with embodiments of the present disclosure. The cross-sectional view of FIG. 9A is taken from the perspective of cutline 9A in FIG. 9B.

Image pixel 902 may be a SPAD-based image pixel and may also be referred to as SPAD-based image pixel 902 or SPAD pixel 902. Although a single instance of image pixel 902 is illustrated in FIGS. 9A and 9B, image pixel 802 may be one of multiple image pixels in an array. For example, image pixel 902 may represent an embodiment of each of the plurality of SPAD-based image pixels 202 in array 120 of SPAD-based semiconductor device 14 described above with reference to FIG. 3.

As shown in FIGS. 9A and 9B, image pixel 902 may include lens layer 909 instead of lens layer 809, but may otherwise include similar features and operate in a similar manner as image pixel 802 described above with reference to FIGS. 8A and 8B. As shown in FIGS. 9A and 9B, lens layer 909 may include a plurality of microlenses 910 distributed across the top surface of planar layer 811.

The plurality of microlenses 910 may be formed with either an organic or an inorganic material. For example, plurality of microlenses 910 may in some embodiments be formed with an inorganic oxide material. In other embodiments, plurality of microlenses 910 may be formed with an organic material, such as an acrylic-based polymer.

The plurality of microlenses 910 may each be configured to focus light received by image pixel 902 into light pipe 850. For example, the upper surface of each of the plurality of microlenses 910 may have a spherical convex shape. The lower surface of each of the plurality of microlenses 910 may have a planar shape. The plurality of microlenses 910 may thus collectively focus light received by image pixel 902 into underlying elements of image pixel 902. In some embodiments, lens layer 909 may also include a planar layer 811. Planar layer 811 may be formed with the same material, such as acrylic-based polymer, as plurality of microlenses 910. As shown in FIG. 9A, the lower surfaces of the plurality of microlenses 910 may sit atop the upper surface of planar layer 811. The inclusion of planar layer 811 may prevent physical stresses incurred during the process of forming microlenses 910 from translating to underlying features of image pixel 902. However, in some embodiments, planar layer 811 may be omitted from lens layer 909, and the plurality of microlenses 910 may sit directly on top of features underlying lens layer 909.

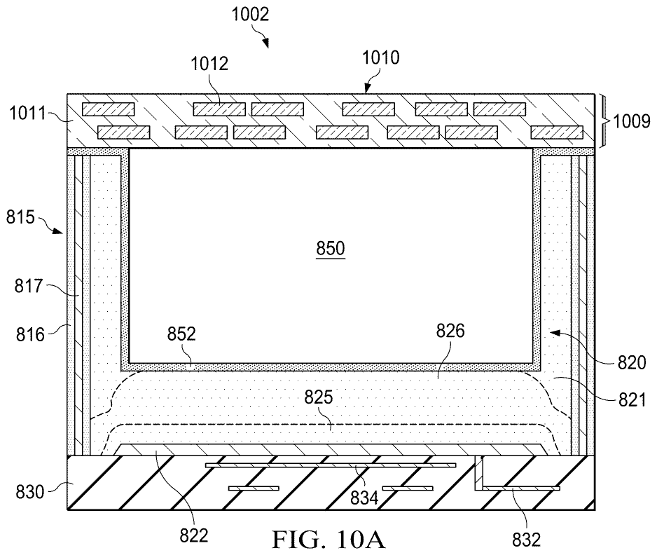

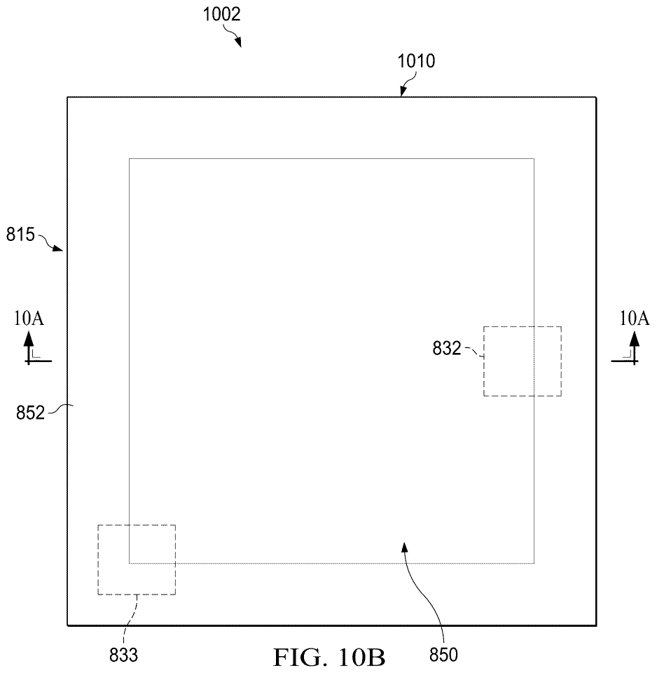

FIG. 10A illustrates a side cross-sectional view of image pixel 1002 in accordance with embodiments of the present disclosure. FIG. 10B illustrates a top view of image pixel 1002 in accordance with embodiments of the present disclosure. The cross-sectional view of FIG. 10A is taken from the perspective of cutline 10A in FIG. 10B.

Image pixel 1002 may be a SPAD-based image pixel and may also be referred to as SPAD-based image pixel 1002 or SPAD pixel 1002. Although a single instance of image pixel 1002 is illustrated in FIGS. 10A and 10B, image pixel 1002 may be one of multiple image pixels in an array. For example, image pixel 1002 may represent an embodiment of each of the plurality of SPAD-based image pixels 202 in array 120 of SPAD-based semiconductor device 14 described above with reference to FIG. 3. As shown in FIGS. 10A and 10B, image pixel 1002 may include lens layer 1009 instead of lens layer 809, but may otherwise include similar features and operate in a similar manner as image pixel 802 described above with reference to FIGS. 8A and 8B.

Lens layer 1009 may include nanophotonic lens 1010. Nanophotonic lens 1010 may include dielectric layer 1011 and a plurality of nanostructures 1012 disposed within dielectric layer 1011. The plurality of nanostructures 1012 may be designed and implemented as three-dimensional structures, such as cuboids, having different sizes and having varying indices of refraction compared to the dielectric material of dielectric layer 1011. In some embodiments, the plurality of nanostructures 1012 may be arranged in multiple layers within dielectric layer 1011. Each of the plurality of nanostructures 1012 may have a first refractive index that may be greater than a second refractive index of dielectric layer 1011. For example, dielectric layer 1011 may comprise silicon dioxide. In such embodiments, the plurality of nanostructures 1012 arranged within dielectric layer 1011 may comprise one or more of silicon nitride and titanium dioxide, which have a higher refractive index than silicon dioxide.

The plurality of nanostructures 1012 may be arranged within dielectric layer 1011 to direct light received by image pixel 1002 into light pipe 850. As light passes through nanophotonic lens 1010, the light may be refracted and diffracted by the nanostructures 1012 due to the different refractive indexes of dielectric layer 1011 and nanostructures 1012. Light may be directed by nanophotonic lens 1010 to areas where the phases of wavelengths of refracted and diffracted light from different nanostructures 1012 align and therefore constructively interfere with each other. Conversely, light may be diffused and directed away from areas where wavelengths of refracted and diffracted light from different nanostructures 1012 are out of phase with each other and therefore destructively interfere with each other.

In some embodiments, nanophotonic lens 1010 may also be configured as a blue-pass filter. For example, the plurality of nanostructures 1012 may be patterned within dielectric layer 1011 to transmit blue light and to block infrared and other wavelengths of light in the visible spectrum. Specifically, the plurality of nanostructures 1012 may be configured and arranged within dielectric layer 1011 such that wavelengths of blue light refracted and diffracted from different nanostructures 1012 constructively interfere with corresponding wavelengths of blue light refracted and diffracted from other nanostructures 1012. In such embodiments, the plurality of nanostructures 1012 may be configured and arranged within dielectric layer 1011 such that infrared and other wavelengths of light in the visible spectrum may destructively interfere with each other. Thus, in such embodiments, blue light may be passed and directed by nanophotonic lens 1010 into light pipe 850, and infrared and other wavelengths of visible light may be blocked.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

What is claimed is:

1. A semiconductor device comprising:
a plurality of image pixels, each image pixel of the plurality of image pixels comprising:
a semiconductor region;
a single-photon avalanche diode formed in the semiconductor region;
an optical structure disposed in the semiconductor region and extending from an upper surface of the semiconductor region into an interior of the semiconductor region; and
a microlens configured to focus light received by the image pixel into the optical structure.

2. The semiconductor device of claim 1, wherein the optical structure extends into a depletion region of the single-photon avalanche diode.

3. The semiconductor device of claim 1, wherein an absorption area for photons of blue light at least partially overlaps with a depletion region of the single-photon avalanche diode.

4. The semiconductor device of claim 1, wherein each image pixel comprises:
a plurality of optical structures disposed in the semiconductor region and extending from the upper surface of the semiconductor region to the interior of the semiconductor region; and
a plurality of microlenses respectively configured to focus light received by the image pixel into the plurality of optical structures.

5. The semiconductor device of claim 1, wherein the optical structure is symmetrically configured about the center of image pixel.

6. The semiconductor device of claim 1, wherein the optical structure has an inverse pyramid shape extending downward from the upper surface of the semiconductor region.

7. The semiconductor device of claim 1, wherein the optical structure is formed along a crystallographic structure of the semiconductor region.

8. The semiconductor device of claim 1, wherein each image pixel is a back-side illuminated image pixel.

9. The semiconductor device of claim 1, wherein each image pixel further comprises a blue-pass filter.

10. An imaging system comprising:
an image processing circuit; and
a semiconductor device communicatively coupled to the image processing circuit and comprising a plurality of image pixels, each image pixel comprising:
a semiconductor region;
a single-photon avalanche diode formed in the semiconductor region;
an optical structure disposed in the semiconductor region and extending from an upper surface of the semiconductor region into an interior of the semiconductor region; and
a microlens configured to focus light received by the image pixel into the optical structure.

11. The imaging system of claim 10, wherein the optical structure extends into a depletion region of the single-photon avalanche diode.

12. The imaging system of claim 10, wherein an absorption area for photons of blue light at least partially overlaps with a depletion region of the single-photon avalanche diode.

13. The imaging system of claim 10, wherein the optical structure has an inverse pyramid shape extending downward from the upper surface of the semiconductor region.

14. A semiconductor device comprising:
a plurality of image pixels, each image pixel of the plurality of image pixels comprising:
a semiconductor region;
a single-photon avalanche diode formed in the semiconductor region; and
a light pipe disposed in the semiconductor region above the single-photon avalanche diode; and
a lens layer configured to focus light received by the image pixel into the light pipe.

15. The semiconductor device of claim 14, wherein each image pixel comprises a plurality of light pipes disposed in the semiconductor region above the single-photon avalanche diode.

16. The semiconductor device of claim 14, wherein the light pipe comprises a same material as the lens layer.

17. The semiconductor device of claim 14, wherein the lens layer comprises a single microlens.

18. The semiconductor device of claim 14, wherein the lens layer comprises a plurality of microlenses each configured to focus light received by the image pixel into the light pipe.

19. The semiconductor device of claim 14, wherein the lens layer comprises a nanophotonic lens including a plurality of nanostructures disposed within a dielectric layer.

20. The semiconductor device of claim 19, wherein the nanophotonic lens is configured as a blue-pass filter.
